(19) United States
(12) Patent Application Publication
(10) Pub. No.: US 2014/0103529 A1
(43) Pub. Date: Apr. 17, 2014

(54) SEMICONDUCTOR DEVICE MANUFACTURING METHOD, SEMICONDUCTOR DEVICE, SEMICONDUCTOR DEVICE MANUFACTURING APPARATUS AND STORAGE MEDIUM

(71) Applicant: Tokyo Electron Limited, Tokyo (JP)

(72) Inventors: Kenji Matsumoto, Nirasaki-Shi (JP); Atsushi Gomi, Nirasaki-Shi (JP); Tatsuo Hatano, Nirasaki-Shi (JP); Tatsufumi Hamada, Nirasaki-Shi (JP)

(73) Assignee: Tokyo Electron Limited, Tokyo (JP)

(21) Appl. No.: 14/105,514

(22) Filed: Dec. 13, 2013

Related U.S. Application Data
(63) Continuation of application No. PCT/JP2012/064844, filed on Jun. 8, 2012.

(30) Foreign Application Priority Data
Jun. 16, 2011 (JP) 2011-134317

(51) Int. Cl. H01L 21/768; H01L 23/532

(52) U.S. Cl. CPC H01L 21/76846; H01L 23/53238
USPC 257/751; 118/620; 438/653

(57) ABSTRACT

In order to obtain a semiconductor device having an embedded electrode with low cost and high reliability, a semiconductor device manufacturing method includes forming a first film made of a metal oxide within an opening which is formed in an insulating film formed on a surface of a substrate; performing a hydrogen radical treatment by irradiating atomic hydrogen to the first film; forming a second film made of a metal within the opening after the performing of the hydrogen radical treatment; and forming an electrode made of a metal within the opening after the forming of the second film.

### CROSS-REFERENCE TO RELATED APPLICATION

This Application is a Continuation of International Application No. PCT/JP2012/064844 filed on Jun. 8, 2012, which claims the benefit of Japanese Patent Application No. 2011-134317 filed on Jun. 16, 2011. The entire disclosure of the prior application is incorporated herein by reference in its entirety.

### TECHNICAL FIELD

The embodiments described herein pertain generally to a semiconductor device manufacturing method, a semiconductor device, a semiconductor device manufacturing apparatus and a storage medium.

### BACKGROUND

Recently, it is required to produce a compact-sized electronic device having high speed and high reliability. To this end, a multilayer wiring structure in which a metal wiring is embedded in an interlayer insulation film is widely employed to obtain a miniaturized semiconductor device featuring high speed and high integration. Copper (Cu), which has low electromigration and low resistance, is generally used as a material for the metal wiring. The multilayer wiring structure is formed through the processes of: forming, e.g., a trench by removing an interlayer insulating film on a certain region until a wiring provided under the interlayer insulating film is exposed; and burying copper in the trench. Here, in order to suppress diffusion of the copper into the interlayer insulating film or the like, the copper film is formed after a barrier film is formed.

Typically, tantalum (Ta), tantalum nitride (TaN) or the like is used as the barrier film. Recently, however, a technique using manganese oxide (MnOₓ) has been proposed to obtain a thin and highly uniform film. Since, however, the adhesion strength of Cu formed on a MnOₓ film is weak, production yield and reliability might be deteriorated. To solve the problem, there has been proposed a method of forming, on the MnOₓ film, a ruthenium (Ru) film having high adhesiveness to Cu and then forming an embedded electrode made of Cu on the Ru film (Patent Documents 1 and 2).

Patent Document 1: Japanese Patent Laid-open Publication No. 2008-300568

Patent Document 2: Japanese Patent Laid-open Publication No. 2010-021447

However, when the Ru film is formed by a CVD (Chemical Vapor Deposition) method on the MnOₓ film which is also formed by the CVD method, there may arise problems such as low nucleation density of Ru, long incubation time for forming the Ru film, high sheet resistance of the formed Ru film, and insufficient adhesiveness between the MnOₓ film and the Ru film.

### SUMMARY

In view of the foregoing, example embodiments provide a semiconductor device in which a trench or the like is formed in an interlayer insulating film; a MnOₓ film and a Ru film are stacked in the trench; and an embedded electrode of Cu or the like is formed on the MnOₓ film and the Ru film, and also provide a semiconductor device manufacturing method and a semiconductor device manufacturing apparatus capable of forming the Ru film having low sheet resistance with a shortened incubation time and achieving high adhesiveness between the MnOₓ film and the Ru film. The example embodiments also provide a storage medium therefor.

In one example embodiment, a semiconductor device manufacturing method includes forming a first film made of a metal oxide within an opening which is formed in an insulating film formed on a surface of a substrate; performing a hydrogen radical treatment by irradiating atomic hydrogen to the first film; forming a second film made of a metal within the opening after the performing of the hydrogen radical treatment; and forming an electrode made of a metal within the opening after the forming of the second film.

The performing of the hydrogen radical treatment may improve one of incubation time decrease, thickness uniformity, sheet resistance and adhesiveness of the second film.

The hydrogen radical treatment may be performed in a state where the substrate may be heated.

The performing of the hydrogen radical treatment may reduce C component in the first film.

The atomic hydrogen may be generated by remote plasma.

The first film may contain an oxide of one or more elements selected from the group consisting of Mg, Al, Ca, Ti, V, Cr, Mn, Fe, Co, Ni, Ge, Sr, Y, Zr, Nb, Mo, Rh, Pd, Sn, Ba, Hf, Ta and Ir.

The first film may contain a Mn oxide.

The first film may be formed by a CVD method, an ALD method or a supercritical CO₂ method.

The first film may be formed by a thermal CVD method, a thermal ALD method, a plasma CVD method, a plasma ALD method or a supercritical CO₂ method.

The second film may contain one or more elements selected from the group consisting of Fe, Co, Ni, Ru, Rh, Pd, Os, Ir and Pt.

The second film may be formed by a CVD method, an ALD method or a supercritical CO₂ method.

The second film may be formed by a thermal CVD method, a thermal ALD method, a plasma CVD method, a plasma ALD method or a supercritical CO₂ method.

The electrode may be made of copper or a material containing copper.

The electrode may be formed by one or more methods selected from the group consisting of a thermal CVD method, a thermal ALD method, a plasma CVD method, a plasma ALD method, a PVD method, an electroplating method, an electroless plating method and a supercritical CO₂ method.

In another example embodiment, a semiconductor device includes a film structure formed by the semiconductor device manufacturing method.

In still another example embodiment, a semiconductor device manufacturing apparatus forms a first film made of a metal oxide within an opening which is formed in an insulating film formed on a surface of a substrate; forms a second film made of a metal within the opening; and forms an electrode made of a metal within the opening. Here, in the semiconductor device manufacturing apparatus, atomic hydrogen is irradiated to the first film.

The semiconductor device manufacturing apparatus may include a remote plasma generating unit configured to generate the atomic hydrogen.

The semiconductor device manufacturing apparatus may include a heating unit configured to heat the substrate.

In still another example embodiment, a computer-readable storage medium has stored thereon computer-executable instructions, in response to execution, cause a system controller of a semiconductor device manufacturing apparatus to perform a semiconductor device manufacturing method.

In accordance with the example embodiments, in the semiconductor device in which the MnOₓ film, the Ru film and the embedded electrode of Cu or the like are formed in the trench, incubation time for forming the Ru film can be shortened, sheet resistance of the Ru film can be lowered and adhesiveness between the MnOₓ film and the Ru film can be improved. Thus, a wiring structure having high reliability can be provided. Further, since the wiring structure is miniaturized with high density, a semiconductor device can be manufactured at a low cost.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a structural diagram (1) of samples 1A and 1B;

FIG. 2 is a graph showing a relationship between a film formation time and a thickness of a Ru film;

FIG. 3 is a graph showing a relationship between a thickness and a sheet resistance of a Ru film;

FIG. 4 is a structural diagram (2) of samples 2A, 2B, 3A and 3B;

FIG. 5 is a structural diagram (3) of samples 4A and 4B;

FIG. 6 is a graph showing a relationship between a depth and a concentration of the sample 2A obtained by SIMS analysis;

FIG. 7 is a graph showing a relationship between a depth and a concentration of the sample 2B obtained by SIMS analysis;

FIG. 8 is a graph showing a relationship between a depth and a concentration of the sample 3A obtained by SIMS analysis;

FIG. 9 is a graph showing a relationship between a depth and a concentration of the sample 3B obtained by SIMS analysis;

FIG. 10 is a graph showing a relationship between a depth and a concentration of the sample 4A obtained by SIMS analysis;

FIG. 11 is a graph showing a relationship between a depth and a concentration of the sample 4B obtained by SIMS analysis;

FIG. 12 is a configuration view of a semiconductor device manufacturing apparatus in accordance with an example embodiment;

FIG. 13 is a configuration view of another semiconductor device manufacturing apparatus in accordance with the example embodiment;

FIG. 14 is a flowchart for describing a semiconductor device manufacturing method in accordance with the example embodiment;

FIG. 15A to FIG. 15C are processing diagrams 1 for describing the semiconductor device manufacturing method in accordance with the example embodiment;

FIG. 16A to FIG. 16C are processing diagrams 2 for describing the semiconductor device manufacturing method in accordance with the example embodiment;

FIG. 17A to FIG. 17C illustrate TEM images of samples 17A, 17B and 17C;

FIG. 18A to FIG. 18C illustrate SEM images (1) of the samples 17A, 17B and 17C;

FIG. 19A and FIG. 19B illustrate SEM images of the samples 17A and 17B;

FIG. 20A to FIG. 20C are SEM images (2) of the samples 17A, 17B and 17C; and

FIG. 21A to FIG. 21C are SEM images (3) of the samples 17A, 17B and 17C.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current example embodiment. Still, the example embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, example embodiments will be described with reference to the accompanying drawings. Like parts will be assigned like reference numerals, and redundant description will be omitted. Manganese oxide may be in the form of, but not limited to, MnO, Mn₃O₄, Mn₂O₃ or MnO₂ depending on a valence number. Here, all of these forms are represented by MnO,ₓ and x denotes a number between 1 and 2 inclusive. Further, although there may be a likelihood that MnSiₓO_{y} (manganese silicate) is formed by reacting with Si which is a constituent component of a substrate, it is assumed herein that MnSiₓO_{y} is included in MnOₓ.

(Investigation (1) of MnOₓ film and Ru film)

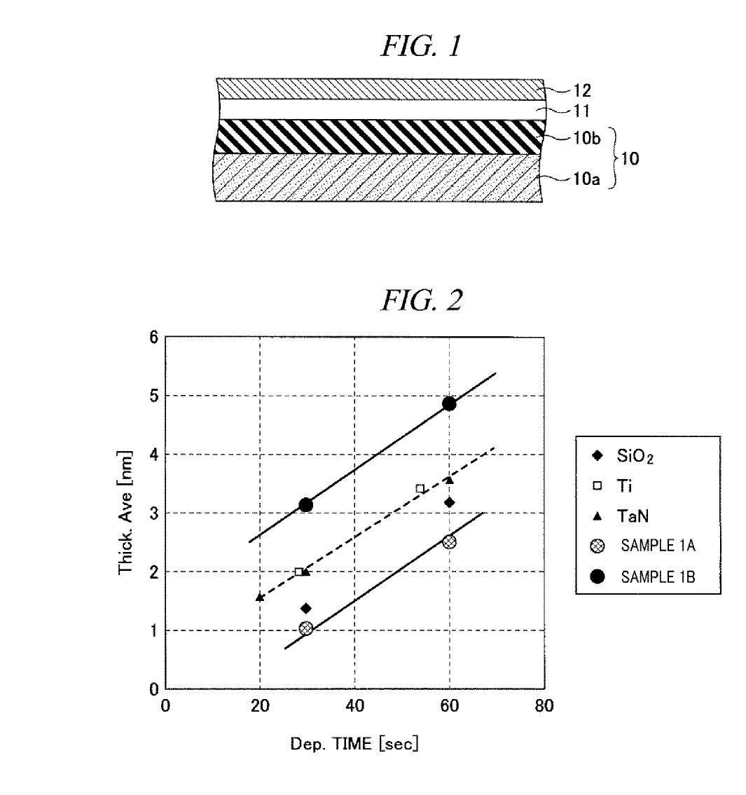

First, researches that have been conducted before reaching the present disclosure will be described. As depicted in FIG. 1, in a structure in which a MnOₓ film 11 as a first film and a Ru film 12 as a second film are formed and stacked on a substrate 10 in sequence, a film forming rate and a sheet resistance of the Ru film 12 will be explained in respective cases where hydrogen radical treatment on the MnOₓ film 11 is performed and not performed.

The substrate 10 in which a TEOS film 10b is formed on a silicon substrate 10a is used. After a MnOₓ film 11 is formed on the TEOS film 10b by the CVD at a substrate temperature of, e.g., about 200° C., a degassing process is performed by heating the substrate 10 to a substrate temperature of, e.g., about 250° C. in an argon atmosphere. Then, a sample 1A is prepared by forming a Ru film 12 on the MnOₓ film 11 by the CVD at a substrate temperature of, e.g., about 200° C. Meanwhile, a sample 1B is prepared by forming a Ru film 12 on the MnOₓ film 11 by the CVD at a substrate temperature of, e.g., about 200° C. after performing a hydrogen radical treatment on the MnOₓ film 11 at a substrate temperature of about 400° C. When forming the MnOₓ film 11 by the CVD, an organic metal material such as (EtCp)₂Mn may be used as a film forming source material, and when forming the Ru film 12 by the CVD, an organic metal material such as Ru₃(CO)₁₂ may be used as a film forming source material.

Here, the hydrogen radical treatment indicates a process of generating atomic hydrogen by remote plasma, plasma, a heating filament, or the like and irradiating the generated atomic hydrogen to a preset surface of the substrate 10.

FIG. 2 is a graph showing a relationship between a film formation time and a thickness of the Ru films in the samples 1A and 1B. For comparison, FIG. 2 also illustrates cases of forming a SiO₂ film, a Ti film and a TaN film instead of the MnOₓ film 11. As shown in the sample 1A, if the Ru film 12 is formed on the MnOₓ film 11 without performing a hydrogen radical treatment on the MnOₓ film 11, it is expected that the Ru film 12 is not deposited until the film formation time of about 10 seconds has elapsed. Thus, it is assumed that there is an incubation time (a time required until the film formation is begun) of about 10 seconds. Meanwhile, in the sample 1B in which the hydrogen radical treatment is performed on the surface of the MnOₓ film 11, an incubation time is assumed to be almost zero. As can be seen from the above, by performing the hydrogen radical treatment on the surface of the MnOₓ film 11, the incubation time for the Ru film 12 to be formed on the MnOₓ film 11 can be shortened.

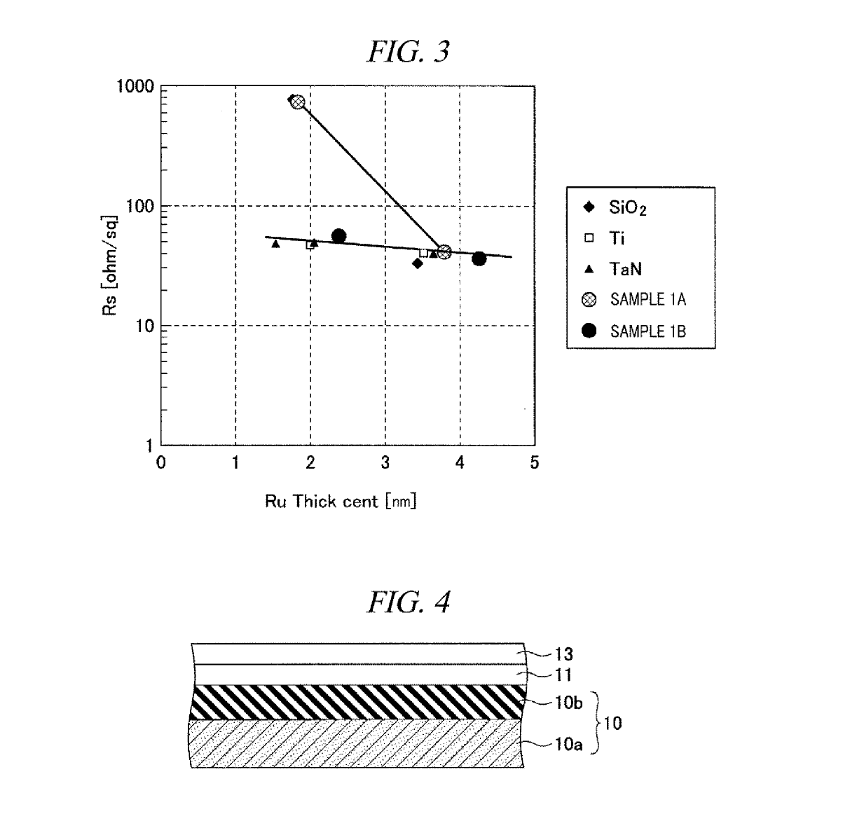

FIG. 3 is a graph showing a relationship between a thickness and a sheet resistance Rs of the Ru films 12 in the samples 1A and 1B. For comparison, FIG. 3 also illustrates the cases of forming the SiO₂ film, the Ti film and the TaN film instead of the MnOₓ film 11. As shown in the sample 1A, if the Ru film 12 is formed on the MnOₓ film 11 without performing the hydrogen radical treatment on the MnOₓ film 11, a sheet resistance Rs of the Ru film 12 and a dependency of the sheet resistance Rs on the thickness of the Ru film 12 are found to be high, as in the case of forming the SiO₂ film as an underlying layer. As can be seen from the sample 1B, however, by performing the hydrogen radical treatment on the surface of the MnOₓ film 11, a sheet resistance Rs of the Ru film 12 formed on the MnOₓ film 11 is reduced and a dependency of the sheet resistance Rs on the thickness of the Ru film 12 is also decreased, as in the cases of forming the Ti film or the TaN film as an underlying layer. Further, though not shown here, uniformity of the thickness of the Ru film 12 formed on the MnOₓ film 11 in the surface of the substrate is also found to be improved.

As can be seen from the foregoing, by performing the hydrogen radical treatment on the surface of the MnOₓ film 11, a film forming rate of the Ru film 12 can be increased, the incubation time for forming the Ru film can be shortened, the sheet resistance Rs of the Ru film can be lowered, and the uniformity of the thickness of the Ru film in the surface of the substrate can be improved. These effects are projected to be made because MnOₓ is reduced to Mn or the like on the surface of the MnOₓ film 11. For another reasons, decrease of an x value in MnO,ₓ conversion of MnOₓ to MnSiₓO_{y}, hydrogen-termination of the surface of MnO,ₓ reduction of residual carbon in the MnOₓ film or a combination of these effects may be considered.

(Investigation (2) of MnOₓ film and Ru film)

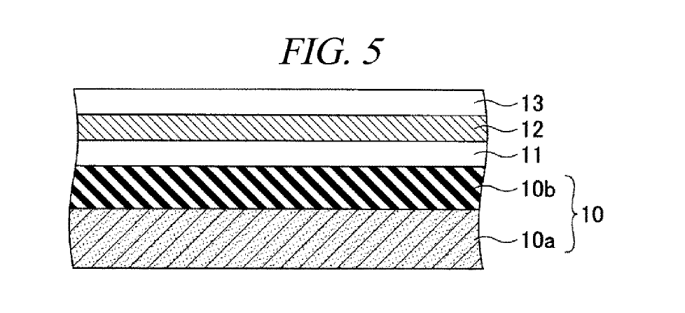

Now, results of conducting composition analysis on samples 2A, 2B, 3A, 3B 4A and 4B by SIMS (Secondary Ion-microprobe Mass Spectrometer) will be explained. Each of the samples 2A, 2B, 3A and 3B is prepared by forming a Cu film 13 on the MnOₓ film 11 formed on the substrate 10, as illustrated in FIG. 4. Meanwhile, each of the samples of 4A and 4B is prepared by forming the Ru film 12 on the MnOₓ film 11 formed on the substrate 10, and then, forming a Cu film 13 on the Ru film 12, as illustrated in FIG. 5.

To elaborate, after the MnOₓ film 11 is formed on the TEOS film 10b of the substrate 10 by the CVD at a substrate temperature of about 200° C., the degassing process is performed by heating the substrate 10 to a substrate temperature of about 250° C. in an argon atmosphere. Then, each of the samples 2A and 2B is prepared by forming the Cu film 13 on the MnOₓ film 11 by the PVD. Meanwhile, each of the samples 3A and 3B is prepared by performing the hydrogen radical treatment on the MnOₓ film 11 at a substrate temperature of about 400° C., and then, forming the Cu film 13 on the MnOₓ film 11 by the PVD. Each of the samples 4A and 4B is prepared by performing the hydrogen radical treatment on the MnOₓ film 11 at a substrate temperature of about 400° C.; forming the Ru film 12 on the MnOₓ film 11 by the CVD at a substrate temperature of about 200° C.; and further forming the Cu film 13 on the Ru film 12 by the PVD. As for each sample, the TEOS film 10b is formed in a thickness of about 100 nm; the MnOₓ film 11 is formed in a thickness of about 4.5 nm; the Ru film 12 is formed in a thickness of about 2 nm; and the Cu film 13 is formed in a thickness of about 100 nm, for example. Further, as for the samples 2B, 3B and 4B, an annealing process is performed at a temperature of, e.g., about 400° C. in an argon atmosphere for about 1 hour.

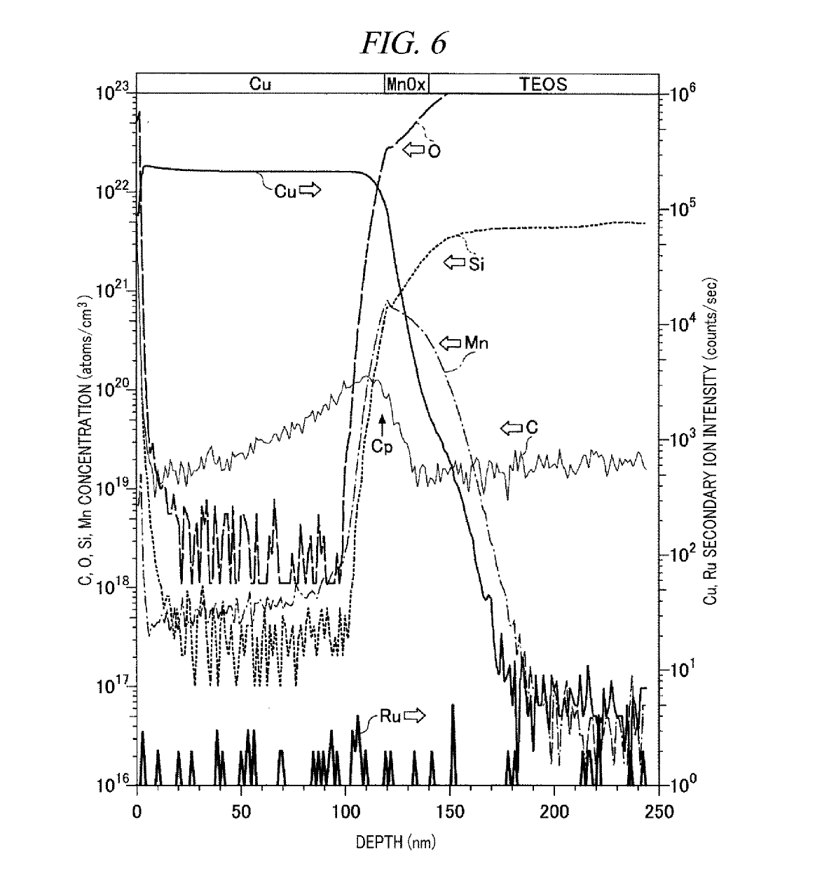

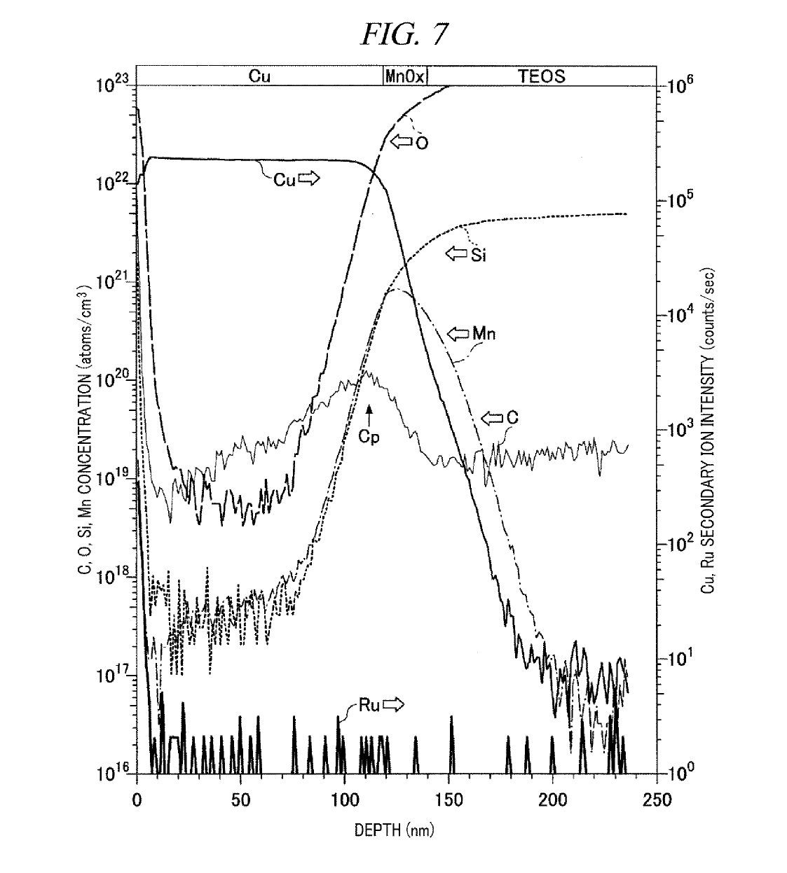

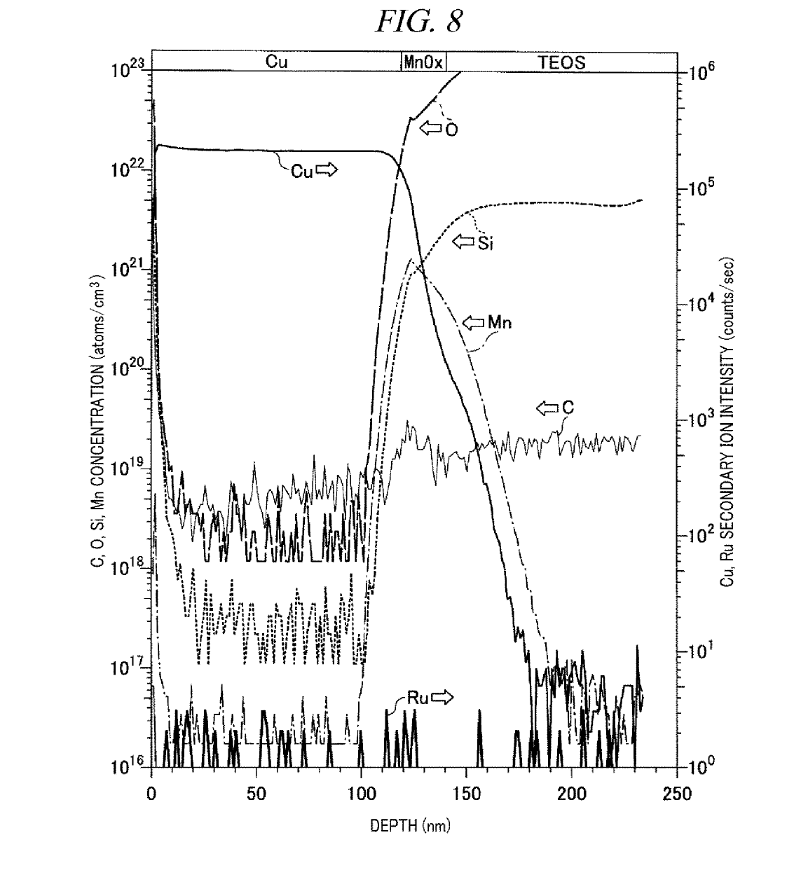

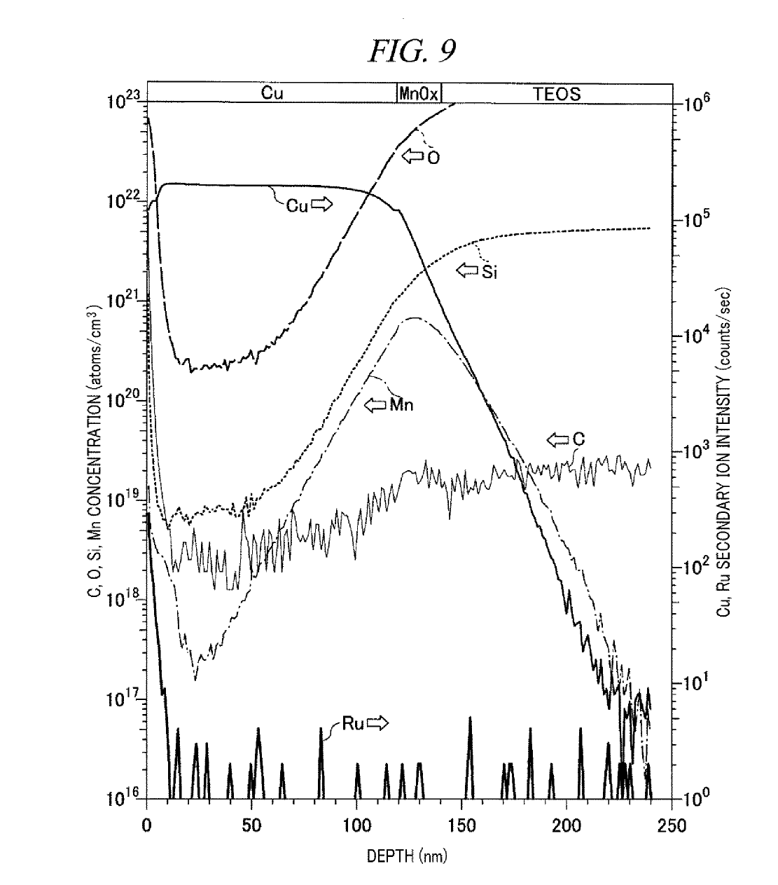

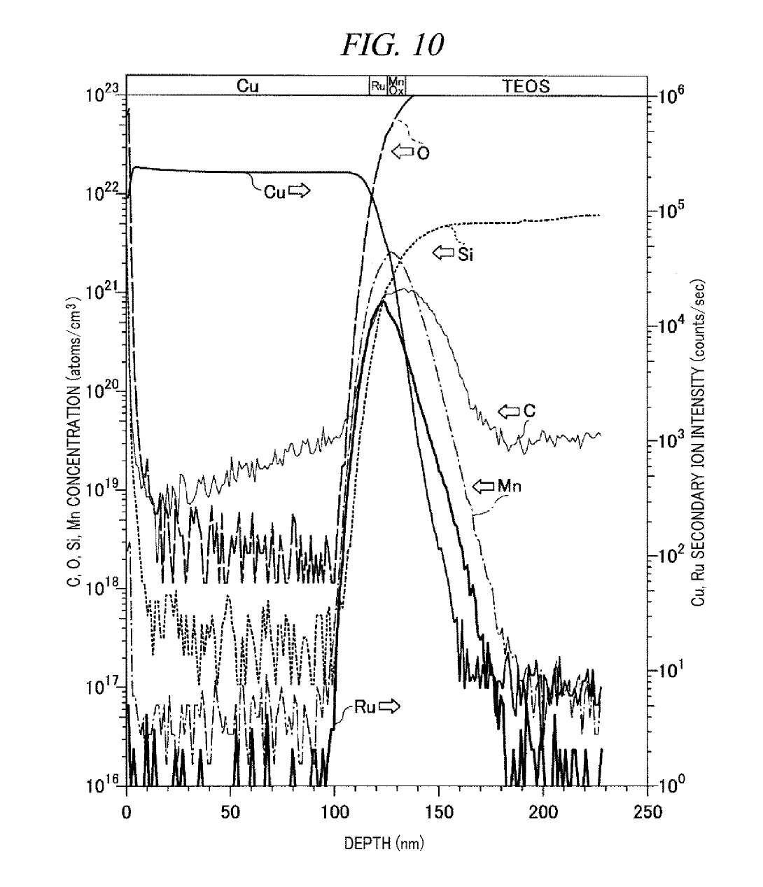

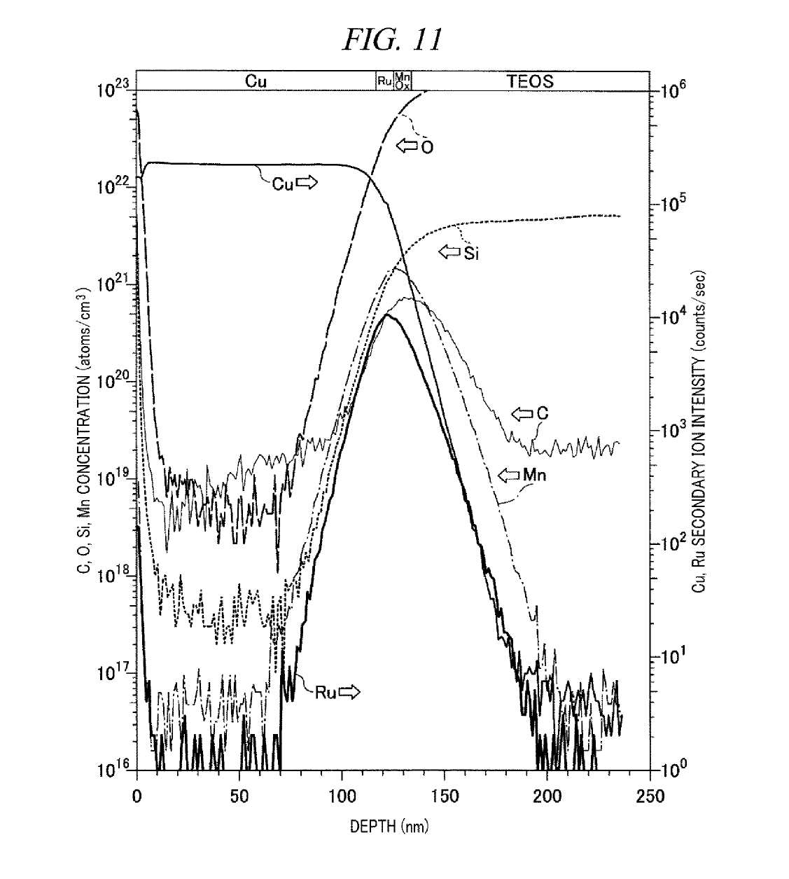

FIG. 6 provides a SIMS analysis result of the sample 2A. FIG. 7 provides a SIMS analysis result of the sample 2B. FIG. 8 provides a SIMS analysis result of the sample 3A. FIG. 9 provides a SIMS analysis result of the sample 3B. FIG. 10 provides a SIMS analysis result of the sample 4A. FIG. 11 provides a SIMS analysis result of the sample 4B. In each of the graphs showing the SIMS analysis results in FIG. 6 to FIG. 11, a horizontal axis represents a film depth, and a vertical axis indicates a concentration of each element.

As can be seen from the comparison of the samples 2A and 2B in FIG. 6 and FIG. 7 with the samples 3A and 3B in FIG. 8 and FIG. 9, by performing the hydrogen radical treatment, it may be possible to reduce a peak Cp of C (carbon), which is assumed to be introduced when the MnOₓ film 11 or the like is formed by the CVD. Further, by performing the hydrogen radical treatment, it may be also possible to remove a part of the C component in the film.

Further, in the sample 2B in FIG. 7 and the sample 3B in FIG. 9, since the Ru film 12 is not formed, Mn is diffused into the Cu film 13 when performing the annealing process at a temperature of about 400° C. In the sample 4B shown in FIG. 11, however, since the Ru film12 is formed, it is possible to suppress Mn from being diffused into the Cu film 13. Further, it is expected that C in the samples 4A and 4B is increased by forming the Ru film 12 through the CVD.

As discussed above, when forming the Ru film 12 on the MnOₓ film 11, a film forming rate of the Ru film 12 can be increased and a sheet resistance of the Ru film 12 can be reduced by performing the hydrogen radical treatment on the MnOₓ film 11 after the MnOₓ film 11 is formed. Furthermore, by performing the hydrogen radical treatment, a part of the C component in the film can be removed.

The present disclosure is based on the above-described investigations.

(Semiconductor device manufacturing apparatus)

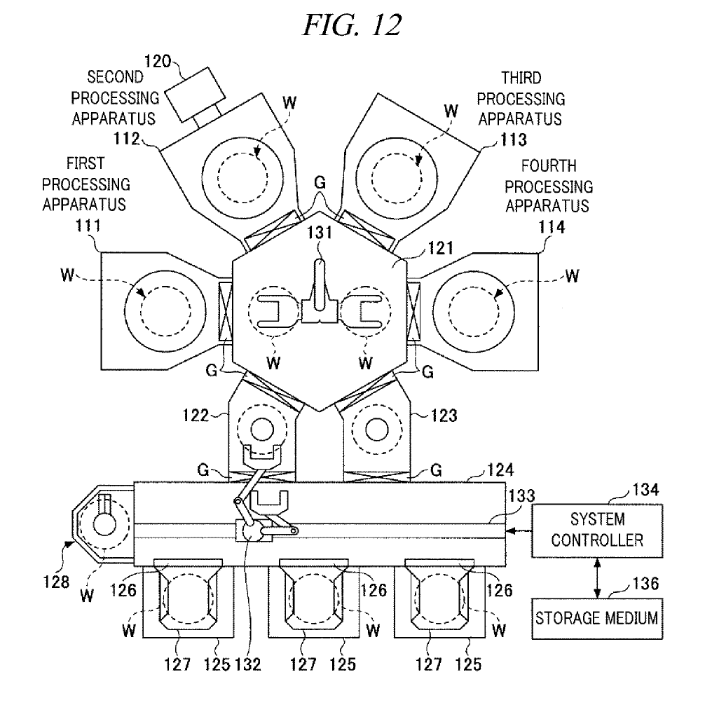

A semiconductor device manufacturing apparatus in accordance with an example embodiment will be described. A wafer W may refer to a substrate or a substrate on which a film is formed. FIG. 12 illustrates a processing system used as the semiconductor device manufacturing apparatus in accordance with the example embodiment. The processing system includes four processing apparatuses 111, 112, 113 and 114; a substantially hexagonal common transfer chamber 121; a first load lock chamber 122 and a second load lock chamber 123 having a load lock function; and an elongated narrow inlet side transfer chamber 124. Gate valves G are provided between the hexagonal common transfer chamber 121 and the processing apparatuses 111 and 114, respectively. Gate valves G are also provided between the common transfer chamber 121 and each of the first and second load lock chambers 122 and 123, and between the inlet side transfer chamber 124 and each of the first and second load lock chambers 122 and 123. Each of the gate valves G can be opened and closed, and as the gate valves G are opened, a wafer W can be transferred between, e.g., the respective apparatuses. By way of non-limiting example, three inlet ports 125 are connected to the inlet side transfer chamber 124 via opening/closing doors 126, and a cassette receptacle 127 configured to accommodate a multiple number of wafers W is mounted in each inlet port 125. Further, an orienter 128 is provided at the inlet side transfer chamber 124 to perform alignment of the wafers W.

A transfer device 131 having a pick that can be contracted and extended is provided in the common transfer chamber 121 to transfer wafers W. Further, an inlet side transfer device 132 having a pick is provided in the inlet side transfer chamber 124 to transfer wafers W. The inlet side transfer device 132 is supported on a guide rail 133 in the inlet side transfer chamber 124 to be slidable along the guide rail 133.

A wafer W is, by way of example, but not limitation, is a silicon wafer and is accommodated in the cassette receptacle 127. The wafer W is transferred from the inlet port 125 into the first load lock chamber 122 or the second load lock chamber 123 by the inlet side transfer device 132. Then, the wafer W transferred into the first load lock chamber 122 or the second load lock chamber 123 is transferred into the four processing apparatuses 111 to 114 by the transfer device 131 provided in the common transfer chamber 121. Further, the wafer W is also transferred between the four processing apparatuses 111 to 114 by the transfer device 131. As the wafer W is moved between the processing apparatuses 111 to 114, the wafer W is subjected to various processes performed in the respective processing apparatuses 111 to 114. The above-stated transfer and processing operations of the wafer W may be controlled by a system controller 134, and programs for implementing the system control or the like are stored in a storage medium 136.

In the present example embodiment, among the four processing apparatuses 111 to 114, the first processing apparatus 111 is configured to form a MnOₓ film; the second processing apparatus 112 is configured to improve the quality of the surface of the MnOₓ film by atomic hydrogen or the like; the third processing apparatus 113 is configured to form a Ru film; and the fourth processing apparatus 114 is configured to form a Cu film. Connected to the second processing apparatus 112 is a remote plasma generating unit 120 configured to generate atomic hydrogen. By irradiating the generated atomic hydrogen to the wafer W, a hydrogen radical treatment is performed. Here, it may be possible to employ a configuration in which the plasma generating unit is provided within the second processing apparatus 112 as long as the atomic hydrogen can be generated. Still alternatively, it may be possible to set up a configuration in which a heating filament is provided within the second processing apparatus 112 and atomic hydrogen is generated by heating.

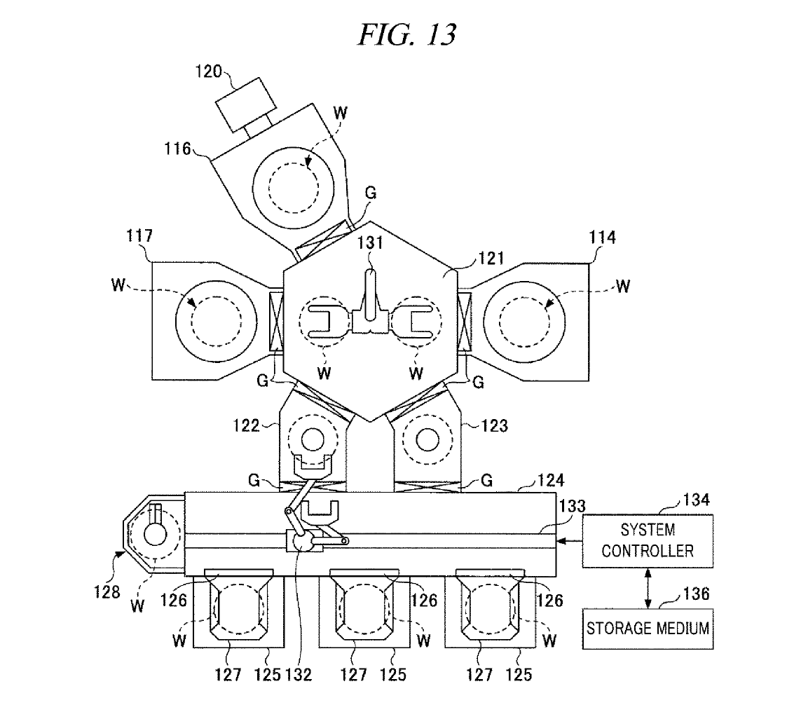

As illustrated in FIG. 13, the processes performed in the first to the third processing apparatuses 111 to 113 can be performed in a single processing apparatus 116. In this case, the processing apparatus 116 connected to the remote plasma generating unit 120 is coupled to the common transfer chamber 121 via a gate valve G. Further, when performing a pre-process of the wafer W prior to forming the MnOₓ film or the like, a processing apparatus 117 configured to perform the pre-process (for example, a degassing process) on the wafer W may be further provided, as depicted in FIG. 13.

(Semiconductor device manufacturing method)

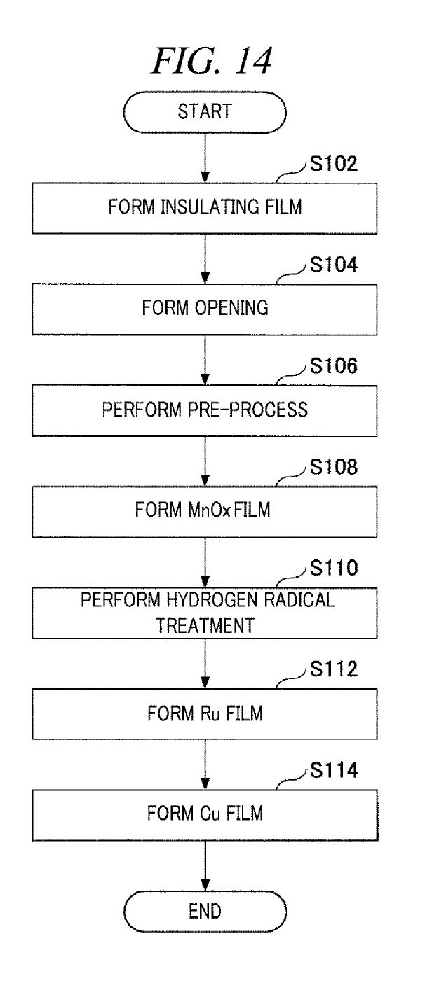

Now, a semiconductor device manufacturing method in accordance with the example embodiment will be discussed with reference to FIG. 14. The semiconductor device manufacturing method of the example embodiment is to form a semiconductor device having a multilayer wiring structure, and, particularly, to form an interlayer wiring structure. Thus, description of a semiconductor device, which has already been formed, and a method therefor is omitted here. Processing may begin at block S102.

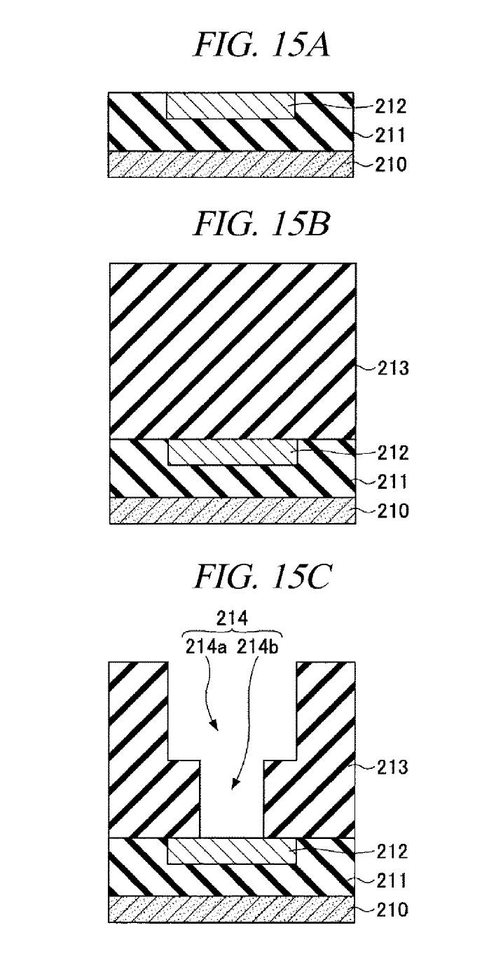

First, at block S102 (Form Insulating Film), an insulating film to be used as an interlayer insulating film is formed. To elaborate, an insulating layer 211 is formed on a substrate 210 such as a silicon substrate, and a wiring layer 212 made of copper or the like is formed on a surface of the insulating layer 211, as illustrated in FIG. 15A. Further, an insulating film 213 made of SiO₂ to be used as an interlayer insulating film is formed, as illustrated in FIG. 15B. The wiring layer 212 is connected to a non-illustrated transistor and other wirings formed on a surface of the substrate 210 or the like. Processing may proceed from S102 to block S104.

At block S104 (Form Opening), an opening 214 is formed in the insulating film 213. To elaborate, as depicted in FIG. 15C, a preset region of the insulating film 213 is removed by, for example, etching until a surface of the wiring layer 212 is exposed. In the present example embodiment, the opening 214 includes a narrow long groove (trench) 214a; and a hole 214b formed at a part of the bottom of the groove 214a. The wiring layer 212 is exposed to the bottom of the hole 214b. By way of example, this opening 214 may be formed by coating photoresist on the surface of the insulating film 213, and then, performing repeatedly an exposure process in an exposure apparatus and an etching process e.g., RIE (Reactive Ion Etching). Processing may proceed from block S104 to block S106.

At block S106 (Perform Pre-process), a degassing process or a cleaning process is performed as a pre-process, so that the inside of the opening 214 is cleaned. As such a cleaning process, a H₂ annealing process, a H₂ plasma process, an Ar plasma process, a dry cleaning process using organic acid may be employed. Processing may proceed from block S106 to block S108.

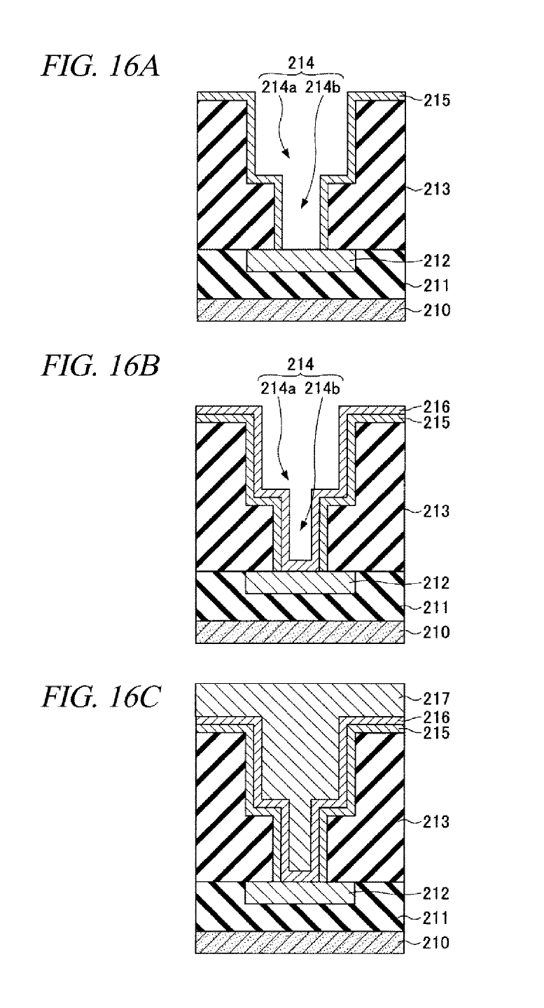

At block S108 (Form MnOₓ Film), a Mn-containing film such as a MnOₓ film serving as a first film is formed (first film forming process). To elaborate, as illustrated in FIG. 16A, the substrate 210 is heated to a temperature of about 200° C., and a MnOₓ film 215 is formed by the CVD with an organic metal source material containing Mn. As a result, the MnOₓ film 215 is formed on a side surface of the opening 214 and the like except for the bottom portion of the hole 214b. Here, a MnSiₓO_{y} film may be formed at an interface between the MnOₓ film 215 and the insulating film 213. Since an oxide film is removed from the region where the wiring layer 212 is exposed, i.e., from the bottom of the hole 214b, the MnOₓ film 215 may not be deposited on the surface of the wiring layer 212 but may be mainly deposited on the side surface of the opening 214 and the like. Further, the thickness of the formed MnOₓ film 215 may be in the range from, e.g., about 0.5 nm to about 5 nm. Besides the CVD method, the MnOₓ film 215 may be formed by ALD (Atomic Layer Deposition). Further, although the example embodiment has been described for the case of using the MnOₓ film 215 as the first film, the first film may be made of any metal oxide. More Desirably, a metal oxide containing an oxide of one or more elements selected from the group consisting of Mg, Al, Ca, Ti, V, Cr, Mn, Fe, Co, Ni, Ge, Sr, Y, Zr, Nb, Mo, Rh, Pd, Sn, Ba, Hf, Ta and Ir may be used as the first film. Processing may proceed from block S108 to block S110.

At block S110 (Perform Hydrogen Radical Treatment), a hydrogen radical treatment is performed (hydrogen radical treatment process). To elaborate, atomic hydrogen is generated by remote plasma, plasma, a heating filament, or the like. The generated atomic hydrogen is irradiated to the surface of the MnOₓ film 215. In the example embodiment, the atomic hydrogen is generated by remote plasma generated in the remote plasma generating unit 120 shown in FIG. 12 and FIG. 13, and the generated atomic hydrogen is irradiated to the surface of of the MnOₓ film 215 on the substrate 210. At this time, it may be desirable to perform a heat treatment as well, and, by way of example, the substrate 210 is heated to about 400° C. The temperature of 400° C. is higher than a film forming temperature for the MnOₓ film 215 and a film forming temperature for a Ru film 216 to be descried later. Here, the hydrogen radical treatment is performed under the following processing conditions of: a substrate temperature of, e.g., about 400° C.; a gas atmosphere of H₂ (10%) and Ar (90%); a processing pressure of about 40 Pa; an input power of about 3 kW; and a processing time of about 60 seconds.

Further, in the hydrogen radical treatment in accordance with the example embodiment, the heating temperature of the substrate 210 may be desirably in the range from, e.g., a room temperature to about 450° C., more desirably, about 200° C. to about 400° C., and most desirably, about 400° C. Further, as for the gas atmosphere, it may be desirable that the concentration of H₂ in Ar ranges from, e.g., about 1% to about 20%, more desirably, about 5% to about 15% , and it may be most desirable that the concentration of H₂ and Ar are set to be about 10% and about 90% , respectively. Further, the processing pressure may be desirably in the range from, e.g., about 10 Pa to about 500 Pa, more desirably, about 20 Pa to about 100 Pa, and most desirably, about 40 Pa. The input power may be desirably set to range from, e.g., about 1 kW to about 5 kW, more desirably, about 2 kW to about 4 kW, and most desirably, about 3 kW. Further, the processing time may be desirably set to be in the range from, e.g., about 5 sec to about 300 sec and, more desirably, about 60 sec. Further, a degassing process (heat treatment) may be performed during the formation of the MnOₓ film 215 at block S108 and the hydrogen radical treatment at block S110. Processing may proceed from block S110 to block S112.

At block S112 (Form Ru Film), a Ru film to be used as a second film is formed (second film forming process). To elaborate, as illustrated in FIG. 16B, the substrate 210 is heated to a temperature of, e.g., about 200° C., and a Ru film 216 is formed by the CVD with an organic metal material containing Ru. The Ru film 216 is a metal material and is formed on the inner surface of the opening 214 including the bottom portion of the hole 214b. That is, the Ru film 216 is formed on the surfaces of the MnOₓ film 215 and the wiring layer 212 exposed to the opening 214. On the bottom portion of the hole 214b, since the MnOₓ film 215 is not formed on the exposed surface of the wiring layer 212 as stated above, the Ru film 216 is formed on the exposed surface of the wiring layer 212.

Further, it may be desirable to maintain a required vacuum degree or a required oxygen partial pressure between the hydrogen radical treatment at block S110 and the formation of the Ru film 216 at block S112. By way of non-limiting example, it may be desirable that a vacuum degree equal to or lower than about 1×10⁻⁴ Pa is maintained. For this reason, desirably, the hydrogen radical treatment at block S110 and the formation of the Ru film 216 at block S112 may be performed in a single chamber, as illustrated in FIG. 13. Alternatively, it may be also desirable that a chamber configured to perform the hydrogen radial treatment and a chamber configured to perform the formation of the Ru film 216 are connected to the common transfer chamber 121 capable of maintaining the required vacuum degree therein, and a wafer W may be transferred between the chamber for the hydrogen radical treatment and the chamber for the formation of the Ru film 216 via the common transfer chamber 121.

Moreover, a cooling process for cooling the substrate 210 to a temperature equal to or lower than a film forming temperature for the Ru film, e.g., a room temperature may be performed between the hydrogen radical treatment at block S110 and the formation of the Ru film 216 at block S112. The thickness of the formed Ru film 216 may be in the range from, e.g., about 0.5 nm to about 5 nm, and the formation of the Ru film 216 may be performed by an ALD method, other than the CVD method as mentioned above. Further, although the present example embodiment has been described for the case of using the Ru film 216 as the second film, the second film may be made of a material containing one or more elements selected from the group consisting of Fe, Co, Ni, Ru, Rh, Pd, Os, Ir and Pt. Further, a material containing one or more platinum group metals may be used as the second film. Processing may proceed from block S112 to block S114.

At block S114 (Form Cu film), a Cu film is formed (electrode forming process). To elaborate, as illustrated in FIG. 16C, a Cu film 217 is formed by one of a CVD method, an ALD method, a PVD method, an electroplating method, an electroless plating method, and a supercritical CO₂ method. Further, the Cu film 217 may be formed by a combination of the aforementioned methods. In the present example embodiment, the Cu film 217 is formed by first forming a thin Cu film by sputtering and then depositing Cu thereon by an electroplating method.

Thereafter, as required, a planarizing process may be performed by, e.g., a CMP (Chemical Mechanical Polishing). By repeating the above-described processes, a required multilayer wiring structure can be formed, and a semiconductor device having the multiplayer wiring structure can be manufactured.

In the above processes, the formation of the MnOₓ film 215 at block S108, the hydrogen radical treatment at block S110 and the formation of the Ru film 216 at block S112 may be performed in the single chamber (processing apparatus) or in different chambers (processing apparatuses).

In accordance with the manufacturing method of the example embodiment, it may be possible to miniaturize a multilayer Cu wiring. Accordingly, it is possible to obtain a highly miniaturized semiconductor device having a high speed. As a consequence, a compact-sized electronic device having a high speed and a high reliability can be manufactured.

(Formed Ru film)

Now, results of observing a TEM (Transmission Electron Microscope) image and a SEM (Scanning Electron Microscope) image of an actually formed Ru film will be explained. To elaborate, there are prepared three samples, i.e., samples 17A, 17B and 17C on which Ru films are formed, and TEM images and SEM images thereof are observed. The sample 17A is produced by the same method as a part of the manufacturing method of the example embodiment described in FIG. 14, i.e., by forming an insulating film, forming a MnOₓ film, performing a hydrogen radical treatment and forming a Ru film in sequence. The sample 17B is produced by performing a hydrogen annealing treatment instead of the hydrogen radical treatment. That is, the sample 17B is produced by forming an insulating film, forming a MnOₓ film, performing the hydrogen annealing treatment and forming a Ru film in sequence. The sample 17C is produced without performing the hydrogen radical treatment and the hydrogen annealing treatment. That is, the sample 17C is produced by forming an insulating film, a MnOₓ film and a Ru film in sequence. Here, the hydrogen radical treatment of the sample 17A and the hydrogen annealing treatment of the sample 17B may be performed at a substantially same temperature.

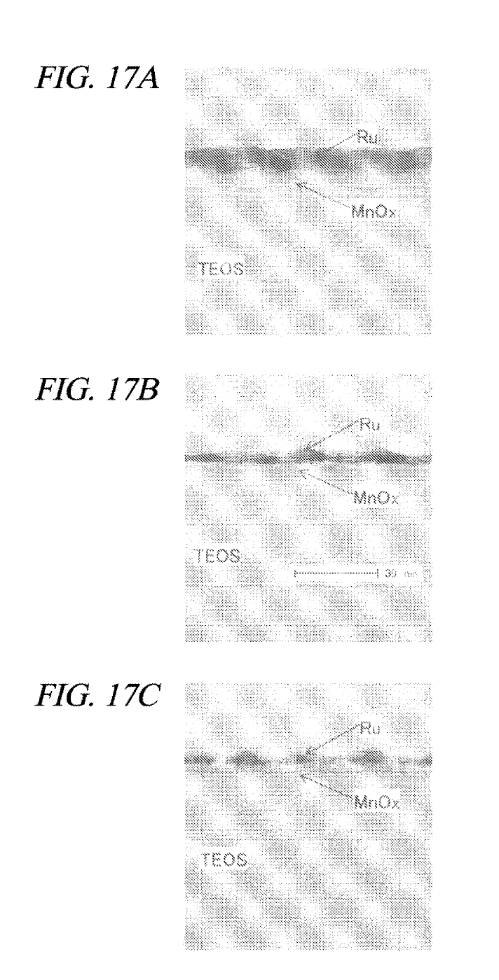

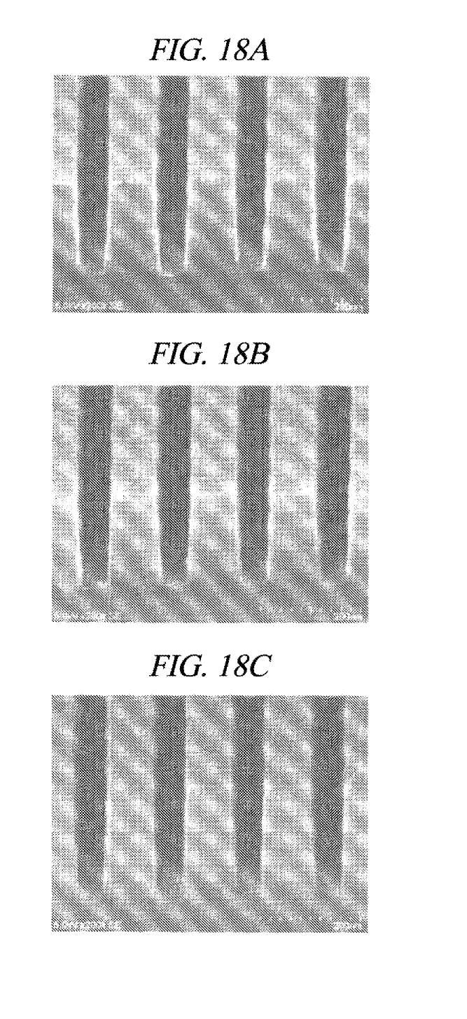

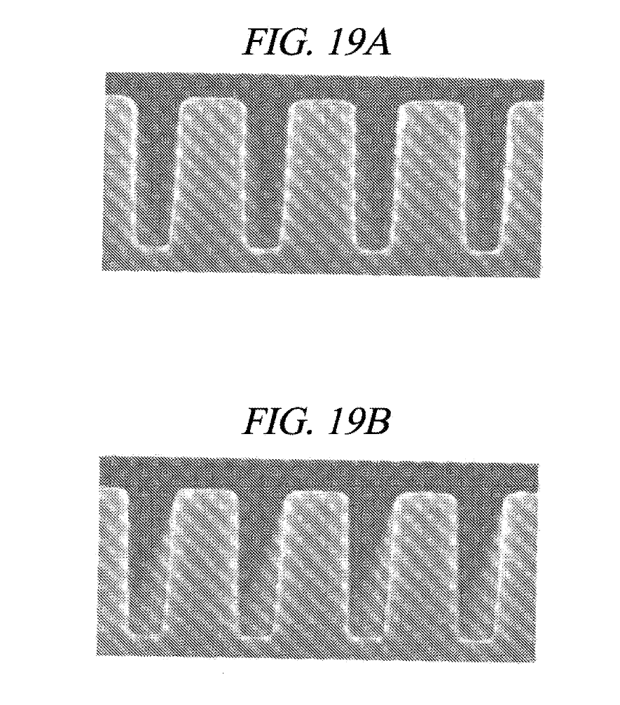

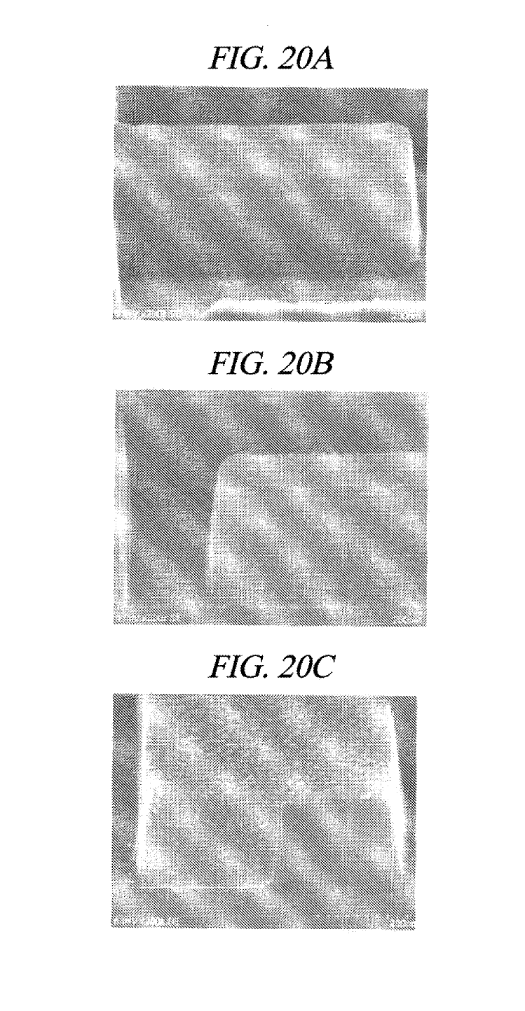

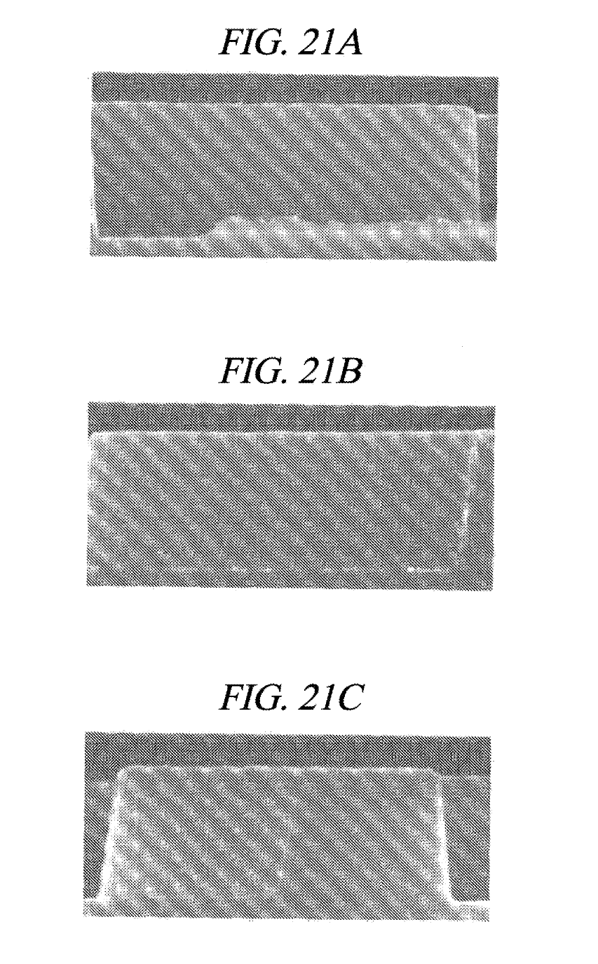

FIG. 17A to FIG. 17C illustrate TEM images of the samples 17A to 17C, and FIG. 18A to FIG. 21C illustrate SEM images of the samples 17A to 17C. Further, FIG. 17A is a TEM image of the sample 17A; FIG. 17B is a TEM image of the sample 17B; and FIG. 17C is a TEM image of the sample 17C. FIG. 18A to FIG. 21C depict SEM images at different angles. FIG. 18A, FIG. 19A, FIG. 20A and FIG. 21A are SEM images of the sample 17A; FIG. 18B, FIG. 19B, FIG. 20B and FIG. 21B are SEM images of the sample 17B; and FIG. 18C, FIG. 20C and FIG. 21C are SEM images of the sample 17C. Further, the samples 17A, 17B and 17C shown in FIG. 17A to FIG. 17C are formed on different substrates from those of the samples 17A, 17B and 17C shown in FIG. 18A to FIG. 21C. FIG. 18A to FIG. 18C show SEM images at regions different from those of FIG. 19A to FIG. 19B. Further, FIG. 20A to FIG. 20C show SEM images at different regions from those of FIG. 21A to FIG. 21C.

As depicted in FIG. 17A to FIG. 17C, a Ru film is formed to be smooth and thick on the sample 17A as compared to the samples 17B and 17C. Since the Ru film on the sample 17A is thicker than those of the samples 17B and 17C, an incubation time may be shortened in the case of the sample 17A. Further, as shown in FIG. 18A to FIG. 21C, the surface of the sample 17A is formed smoothly with less irregularities than those of the samples 17B and 17C.

As can be seen from the above comparison, a remarkably improved effect can be achieved by performing the hydrogen radical treatment in the semiconductor device manufacturing method of the example embodiment, as compared to the case without performing the hydrogen radical treatment and the case of performing the hydrogen annealing treatment instead of the hydrogen radical treatment.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

This international application claims priority to Japanese Patent Application No. 2011-134317, filed on Jun. 16, 2011, which application is hereby incorporated by reference in its entirety.

We claim:

1. A semiconductor device manufacturing method, comprising:
forming a first film made of a metal oxide within an opening which is formed in an insulating film formed on a surface of a substrate;
performing a hydrogen radical treatment by irradiating atomic hydrogen to the first film;
forming a second film made of a metal within the opening after the performing of the hydrogen radical treatment; and
forming an electrode made of a metal within the opening after the forming of the second film.

2. The semiconductor device manufacturing method of claim 1,
wherein the performing of the hydrogen radical treatment improves one of incubation time decrease, thickness uniformity, sheet resistance and adhesiveness of the second film.

3. The semiconductor device manufacturing method of claim 1,
wherein the hydrogen radical treatment is performed in a state where the substrate is heated.

4. The semiconductor device manufacturing method of claim 1,
wherein the performing of the hydrogen radical treatment reduces C component in the first film.

5. The semiconductor device manufacturing method of claim 1,
wherein the atomic hydrogen is generated by remote plasma.

6. The semiconductor device manufacturing method of claim 1,
wherein the first film contains an oxide of one or more elements selected from the group consisting of Mg, Al, Ca, Ti, V, Cr, Mn, Fe, Co, Ni, Ge, Sr, Y, Zr, Nb, Mo, Rh, Pd, Sn, Ba, Hf, Ta and Ir.

7. The semiconductor device manufacturing method of claim 1,
wherein the first film contains a Mn oxide.

8. The semiconductor device manufacturing method of claim 1,
wherein the first film is formed by a CVD method, an ALD method or a supercritical CO₂ method.

9. The semiconductor device manufacturing method of claim 1,
wherein the first film is formed by a thermal CVD method, a thermal ALD method, a plasma CVD method, a plasma ALD method or a supercritical CO₂ method.

10. The semiconductor device manufacturing method of claim 1,
wherein the second film contains one or more elements selected from the group consisting of Fe, Co, Ni, Ru, Rh, Pd, Os, Ir and Pt.

11. The semiconductor device manufacturing method of claim 1,
wherein the second film is formed by a CVD method, an ALD method or a supercritical CO₂ method.

12. The semiconductor device manufacturing method of claim 1,
wherein the second film is formed by a thermal CVD method, a thermal ALD method, a plasma CVD method, a plasma ALD method or a supercritical CO₂ method.

13. The semiconductor device manufacturing method of claim 1,
wherein the electrode is made of copper or a material containing copper.

14. The semiconductor device manufacturing method of claim 1,
wherein the electrode is formed by one or more methods selected from the group consisting of a thermal CVD method, a thermal ALD method, a plasma CVD method, a plasma ALD method, a PVD method, an electroplating method, an electroless plating method and a supercritical CO₂ method.

15. A semiconductor device comprising a film structure formed by a semiconductor device manufacturing method as claimed in claim 1.

16. A semiconductor device manufacturing apparatus that forms a first film made of a metal oxide within an opening which is formed in an insulating film formed on a surface of a substrate; forms a second film made of a metal within the opening; and forms an electrode made of a metal within the opening,
wherein atomic hydrogen is irradiated to the first film.

17. The semiconductor device manufacturing apparatus of claim 16, comprising:
a remote plasma generating unit configured to generate the atomic hydrogen.

18. The semiconductor device manufacturing apparatus of claim 16, comprising:
a heating unit configured to heat the substrate.

19. A computer-readable storage medium having stored thereon computer-executable instructions that, in response to execution, cause a system controller of a semiconductor device manufacturing apparatus to perform a semiconductor device manufacturing method as claimed in claim 1.
